(19) United States
(12) Patent Application Publication
(10) Pub. No.: US 2026/0290713 A1
(43) Pub. Date: Sep. 24, 2026

(54) FAILSAFE OHMIC-CAPACITIVE MEMBRANE ACTUATOR-BASED RADIO FREQUENCY SWITCH

(71) Applicant: Dell Products L.P., Round Rock, TX (US)

(72) Inventors: Tejinder Singh, Manotick (CA); Navjot Kaur Khaira, Manotick (CA)

(21) Appl. No.: 19/085,868

(22) Filed: Mar. 20, 2025

(51) Int. Cl. H01H 1/00; B81B 7/02; H01P 1/12

(52) U.S. Cl. CPC H01H 1/0036; B81B 7/02; H01P 1/127; B81B 2201/014; B81B 2203/0118; B81B 2203/0127; H01H 2001/0063; H01H 2001/0084

(57) ABSTRACT

The technology described herein is directed towards a micro-electromechanical systems (MEMS) switch that combines ohmic and capacitive membranes. When actuated, the ohmic membrane contacts a radio frequency (RF) line allowing low-loss signal continuity; when the capacitive membrane is simultaneously de-actuated, an RF signal path is obtained. If the ohmic membrane fails actuated, control of the capacitive membrane controls the signal path; if the ohmic membrane fails in its de-actuated state, the RF signal is decoupled from the signal path, protecting any connected circuitry. If the capacitive membrane fails de-actuated, control of the ohmic membrane controls the signal path; if the capacitive membrane fails in its actuated state, the RF signal is shunted to ground, protecting any connected circuitry. In one implementation, the combined ohmic and capacitive membrane pair is one of two pairs on a switch device, with another ohmic and capacitive membrane pair corresponding to a different signal path.

### BACKGROUND

Radio frequency (RF) switches control the routing of RF signals in communication systems, and are used for tasks like antenna selection and signal path switching. Common types of RF switches include PIN diodes, FET (field effect transistor)/GaN (Gallium Nitride) switches, and MEMS (micro-electromechanical systems) switches, each with their own characteristics in terms of speed, power consumption, and performance.

RF switches are used in devices such as mobile phones, base stations, and phased array antennas for tasks like signal routing, antenna switching, and phase shifting. Important factors for RF switches include insertion loss (signal loss through the switch), isolation (preventing signal leakage between paths), and switching speed (how quickly the switch changes states). Existing RF switches often suffer from at least one of high insertion loss, poor isolation, and/or complex fabrication processes, limiting their applicability in space-constrained high-performance scenarios.

### BRIEF DESCRIPTION OF THE DRAWINGS

The technology described herein is illustrated by way of example and not limited to the accompanying figures in which like reference numerals indicate similar elements and in which:

FIG. 1 is a top view representation of an example failsafe ohmic-capacitive membrane actuator-based radio frequency (RF) switch device layout, in accordance with various embodiments and implementations of the subject disclosure.

FIG. 2 is a top view representation of the example switch device of FIG. 1, in accordance with various embodiments and implementations of the subject disclosure.

FIG. 3 is a three-dimensional (3D) top perspective view representation of some of the example switch device components of FIG. 1, in accordance with various embodiments and implementations of the subject disclosure.

FIGS. 4A and 4B are side views of an example micromembrane actuator showing the general operating principle (open, FIG. 4A, and closed, FIG. 4B) via a cantilever-based connector, in accordance with various example embodiments and implementations of the subject disclosure.

FIG. 5 is a zoomed-in, 3D representation of a portion of FIG. 3 highlighting a metallic contact and capacitive contact, in accordance with various embodiments and implementations of the subject disclosure.

FIG. 6 is a top view representation of a pair of ohmic-capacitive membranes switches, with the left side showing the capacitive switch B, and the right side showing the ohmic switch A, in accordance with various embodiments and implementations of the subject disclosure.

FIG. 7A is a 3D top view representation of an example capacitive membrane switch, in accordance with various embodiments and implementations of the subject disclosure.

FIG. 7B is a 3D bottom view representation of an example capacitive membrane switch, in accordance with various embodiments and implementations of the subject disclosure.

FIG. 7C is a cross-sectional view representation of an example capacitive membrane switch, in accordance with various embodiments and implementations of the subject disclosure.

FIG. 8A is a 3D top view representation of an example ohmic membrane switch, in accordance with various embodiments and implementations of the subject disclosure.

FIG. 8B is a 3D bottom view representation of an example ohmic membrane switch, in accordance with various embodiments and implementations of the subject disclosure.

FIG. 8C is a cross-sectional representation of an example ohmic membrane switch, in accordance with various embodiments and implementations of the subject disclosure.

FIGS. 9A, 9B, 9C, 9D, 9E, 10A, 10B, 10C, 10D and 10E show an example manufacturing process for fabricating an example ohmic-capacitive membrane-based switch device, in accordance with various embodiments and implementations of the subject disclosure.

FIG. 11 is an equivalent circuit model of the example ohmic-capacitive switch, in accordance with various embodiments and implementations of the subject disclosure.

FIG. 12A is a graphical representation of capacitance changing with frequency for the equivalent circuit model, in accordance with various embodiments and implementations of the subject disclosure.

FIG. 12B is a graphical representation of resistance and inductance changing with frequency for the equivalent circuit model, in accordance with various embodiments and implementations of the subject disclosure.

FIG. 13A is a graphical representation of quality factor (Q-factor) changing with frequency for the equivalent circuit model, in accordance with various embodiments and implementations of the subject disclosure.

FIG. 13B is a graphical representation of RF performance response showing evaluated return loss, in accordance with various embodiments and implementations of the subject disclosure.

FIG. 14A is a graphical representation of RF performance response showing evaluated isolation, in accordance with various embodiments and implementations of the subject disclosure.

FIG. 14B is a graphical representation of RF performance response showing evaluated insertion loss, in accordance with various embodiments and implementations of the subject disclosure.

FIG. 15 is a flow diagram showing example operations related to transmitting RF signals via a switch by controlling an ohmic membrane switch and a capacitive membrane switch, in accordance with various aspects and implementations of the subject disclosure.

### DETAILED DESCRIPTION

Various implementations and embodiments of the technology described herein are generally directed towards compact (1 mm×0.5 mm) failsafe multiport switch designed for RF applications, based on a micro-electromechanical systems (MEMS) switch that combines both ohmic and capacitive membranes, e.g., operating at a unified voltage bias. As will be understood, the switch device facilitates efficient radio frequency (RF) signal routing while generally ensuring failsafe operation.

As described herein, the technology described herein incorporates ohmic membranes that provide direct contact with the RF line when actuated, allowing signal continuity with low insertion loss, and capacitive membranes that utilize a dielectric layer on the RF line and create a shunt to ground when actuated. The shunting provides a failsafe route that blocks the signal in the event that the capacitive switch fails by remaining in the down state (stuck as if actuated even when not intended to be), thereby protecting any connected circuitry. Further, if the ohmic switch remains in the down state as if actuated, the switch device continues to operate via the capacitive switch (typically) remaining operational; if the ohmic switch remains in the up state as if de-actuated, the signal cannot reach the RF signal output port, protecting any connected circuitry. Still further, if the capacitive switch remains in the up state as if de-actuated, the switch device continues to operate via the ohmic switch (typically) remaining operational. This failsafe configuration ensures continued functionality even if one membrane fails due to reliability issues.

It should be understood that any of the examples and/or descriptions herein are non-limiting. Thus, any of the embodiments, example embodiments, concepts, structures, functionalities or examples described herein are non-limiting, and the technology may be used in various ways that provide benefits and advantages in communications and computing in general.

Reference throughout this specification to “one embodiment,” “an embodiment,” “one implementation,” “an implementation,” etc. means that a particular feature, structure, characteristic and/or attribute described in connection with the embodiment/implementation can be included in at least one embodiment/implementation. Thus, the appearances of such a phrase “in one embodiment,” “in an implementation,” etc. in various places throughout this specification are not necessarily all referring to the same embodiment/implementation. Furthermore, the particular features, structures, characteristics and/or attributes may be combined in any suitable manner in one or more embodiments/implementations. Repetitive description of like elements employed in respective embodiments may be omitted for sake of brevity.

The detailed description is merely illustrative and is not intended to limit embodiments and/or application or uses of embodiments. Furthermore, there is no intention to be bound by any expressed or implied information presented in the preceding sections, or in the Detailed Description section. Further, it is to be understood that the present disclosure will be described in terms of a given illustrative architecture; however, other architectures, structures, materials and process features, and steps can be varied within the scope of the present disclosure.

It also should be noted that terms used herein, such as “optimize,” “optimization,” “optimal,” “optimally” and the like only represent objectives to move towards a more optimal state, rather than necessarily obtaining ideal results. Similarly, “maximize” means moving towards a maximal state (e.g., up to some practical limit), not necessarily achieving such a state, and so on.

It will also be understood that when an element such as a layer, region or substrate is referred to as being “on” or “over” “atop” “above” “beneath” “below” and so forth with respect to another element, it can be directly on the other element or intervening elements can also be present. In contrast, only if and when an element is referred to as being “directly on” or “directly over” another element, are there no intervening element(s) present. Note that orientation is generally relative; e.g., “on” or “over” can be flipped, and if so, can be considered unchanged, even if technically appearing to be under or below/beneath when represented in a flipped orientation. It will also be understood that when an element is referred to as being “connected” or “coupled” to another element, it can be directly connected or coupled to the other element or intervening elements can be present. In contrast, only if and when an element is referred to as being “directly connected” or “directly coupled” to another element, are there no intervening element(s) present.

The following detailed description is merely illustrative and is not intended to limit embodiments and/or application or uses of embodiments. Furthermore, there is no intention to be bound by any expressed or implied information presented in the preceding sections, or in the Detailed Description section.

One or more example embodiments are now described with reference to the drawings, in which example components, graphs and/or operations are shown, and in which like referenced numerals are used to refer to like elements throughout. In the following description, for purposes of explanation, numerous specific details are set forth in order to provide a more thorough understanding of the one or more embodiments. It is evident, however, in various cases, that the one or more embodiments can be practiced without these specific details, and that the subject disclosure may be embodied in many different forms and should not be construed as limited to the examples set forth herein.

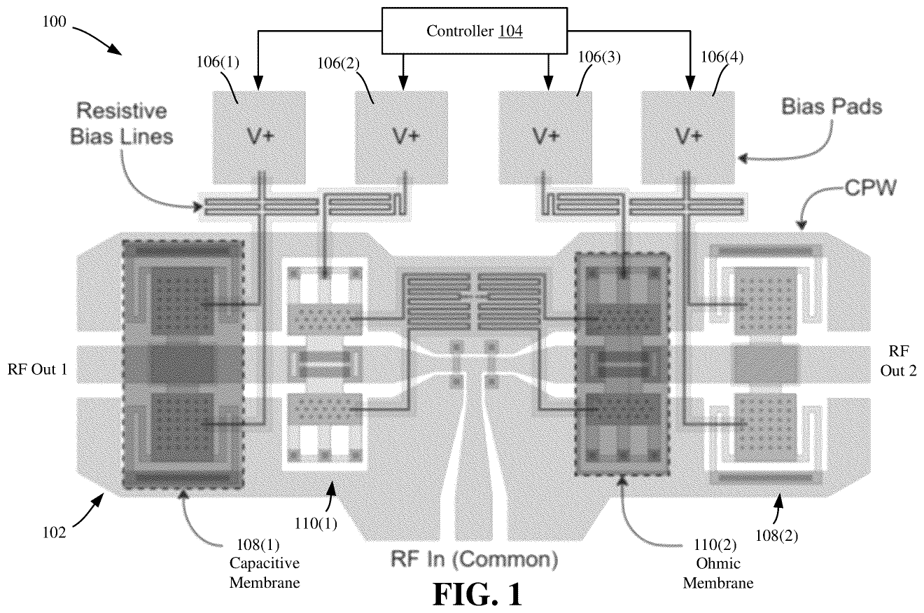

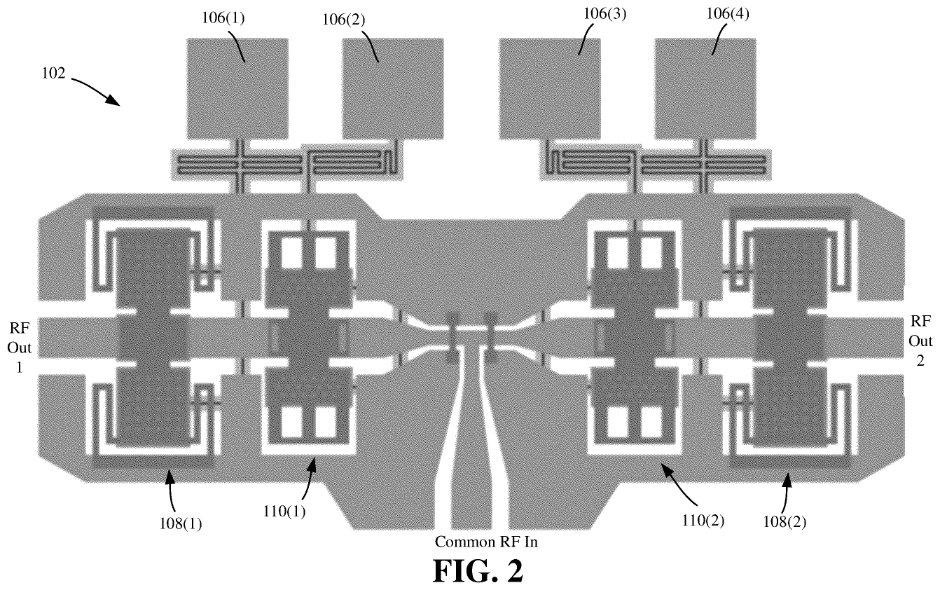

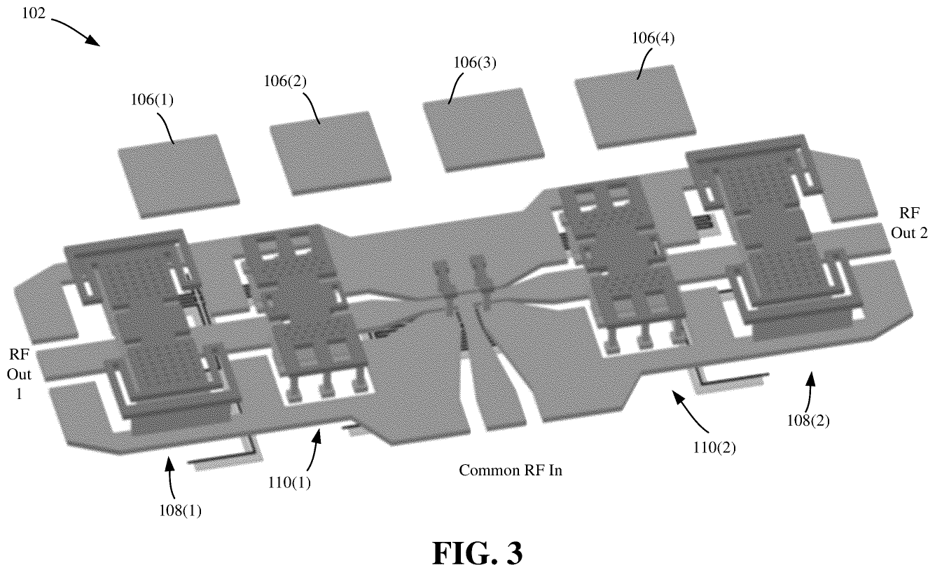

FIG. 1 shows an example top-view layout of one implementation of a system 100 including a MEMS RF switch (device) 102 coupled to a controller 104; FIGS. 2 and 3 are top and three-dimensional (exploded with some components omitted) views of the device 102, respectively. As will be understood, the controller 104 controls operation of the MEMS RF switch device 102 by selectively applying voltage (V+) to bias pads. The bias pads are coupled to electrodes of the MEMS RF switch device 102 through resistive lines configured for suitable actuation of the switch components (including RC time constant) as described herein. Note that the signal path from the RF In port to one of the output ports (RF Out 1 or RF Out 2) is a coplanar waveguide type of path, with the RF signal between RF ground.

In one implementation, there are four bias pads 106(1)-106(4), two bias pads 106(1) and 106(4) corresponding to two capacitive membrane switches 108(1) and 108(2), and two other bias pads 106(2) and 106(3) corresponding to two ohmic membrane switches 110(1) and 110(2). Depending on which output port is selected to receive the incoming RF signals from the (common/shared) RF input port, an ohmic membrane and capacitive membrane pair are controlled as described herein to provide a signal path that couples the RF signals to the selected output port. Thus, to route RF signals at the input port to the RF output port (RF Out 1), the ohmic membrane 110(1) and capacitive membrane 108(1) are controlled. To route RF signals at the input port to the RF output port (RF Out 2), the ohmic membrane 110(2) and capacitive membrane 108(2) are controlled. Typically, only one signal path is used at a time, although it is feasible to split the incoming RF signals to both signal paths. Further, although a two-output port device 102 is generally described in the examples herein, these are nonlimiting examples, and a single output port device can be used (e.g., to controllably couple/decouple the RF signals to another device), or a multiport device with more than two output ports can be used.

Note that the drawings herein including FIG. 1 show the ohmic membrane switch deployed in between the RF input port and the capacitive membrane switch, with the capacitive membrane switch deployed in between the ohmic membrane switch and the RF output port. However, it should be understood that alternatively, the ohmic and capacitive switches can be placed interchangeably, that is, the device can be designed regardless of whether the RF input port is near the ohmic switch or the output port is near the ohmic switch, as long as the functionality remains the same.

The MEMS switch 102 thus combines a pair of ohmic and capacitive membranes, which in one implementation operates at a unified voltage bias, enabling efficient RF signal routing in (mostly) failsafe operation. In general, ohmic membranes provide direct contact with the RF line when actuated, allowing signal continuity with low insertion loss. Capacitive membranes utilize a dielectric layer on the RF line and create a shunt to ground when actuated due to increased capacitance resulting from the shortened distance, providing a failsafe route that blocks the signal in failure conditions. Optimized flexures minimize von Mises stress, reducing stiffness and enhancing mechanical reliability. This failsafe configuration ensures continued functionality even if one membrane fails due to reliability issues.

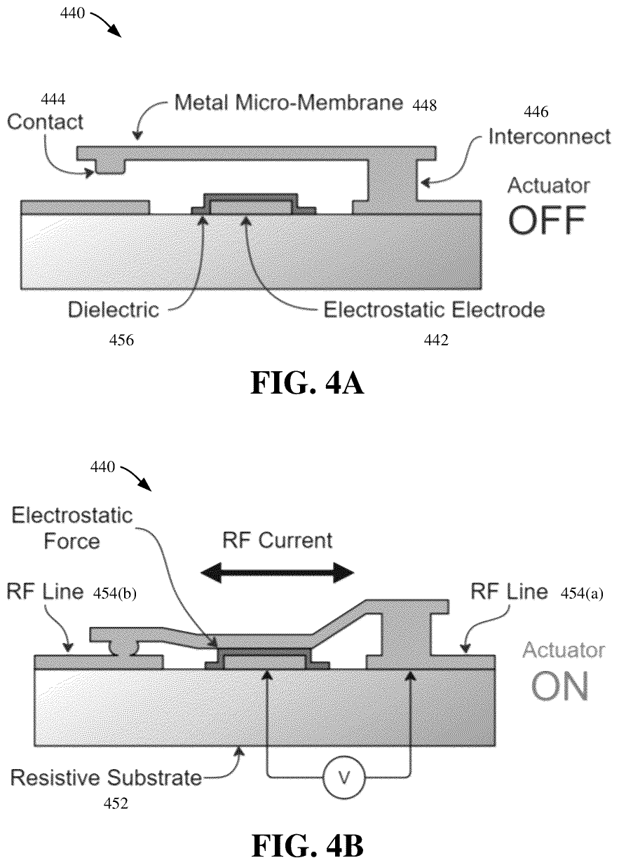

Turning to micromembrane switches in general, FIG. 4A shows an example cantilever type micromembrane actuator 440 in an actuator OFF State, and FIG. 4B shows the example cantilever type micromembrane actuator 440 in an actuator ON state. When no voltage (or too low of a voltage to actuate) is applied to the electrostatic electrode 442 as in FIG. 4A, the micromembrane's contact 444 remains in a lifted state due to the structural configuration of the metal micromembrane 448. In this OFF state, RF current (e.g., obtained an interconnect 446) cannot flow across the RF line, effectively isolating the circuit.

FIG. 4B shows electrostatic actuation, in which applying a voltage V difference to the electrode (relative to ground) creates an electrostatic force that pulls the micromembrane 448 down towards the resistive substrate 452. This electrostatic force overcomes the membrane's structural tension, bringing its contact 444 into contact with the RF line 454(b) at its non-anchored end. In this actuator ON state, the electrical coupling between the micromembrane and RF line is established, allowing RF current to pass through. The RF signal can then flow across the circuit, enabling connectivity between the RF lines 454(a) and 454(b). Note that FIG. 4 shows a dielectric 456 that electrically insulates the electrostatic electrode 442 from the RF lines 454(a) and 454(b).

Note that in general, MEMS-based RF switches face significant commercialization barriers due to complex fabrication processes and reliability issues. Frequent failures due to stiction, micro-welding, and stress-induced failures in switch membranes have limited the application of MEMS in reliable, high-performance RF systems. Described herein is a compact, reliable, and failsafe MEMS switch that can address these challenges while maintaining high performance in RF signal routing applications.

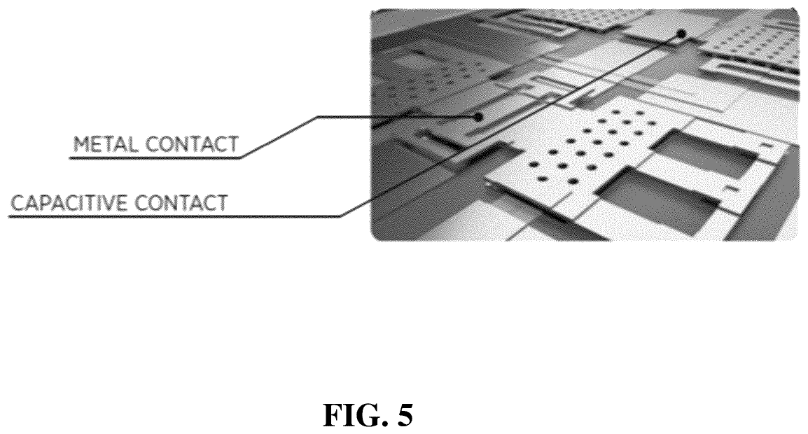

FIG. 5 shows a zoomed-in 3D view of a portion of the device of FIG. 3. Note that unlike the dual membrane switch technology described herein, conventional solutions have focused on single-type MEMS switches (either ohmic or capacitive) with limited failsafe capabilities. In general, ohmic switches provide low insertion loss, but are susceptible to issues such as micro-welding and contact degradation. Capacitive switches offer enhanced durability, but suffer from signal loss in certain applications. MEMS for RF applications are not fully commercialized due to complex manufacturability and various reliability concerns.

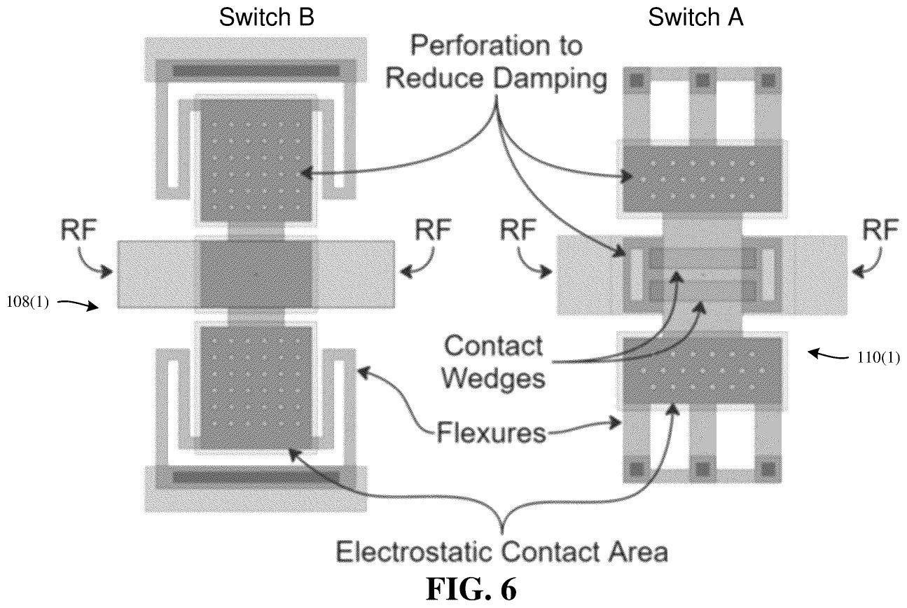

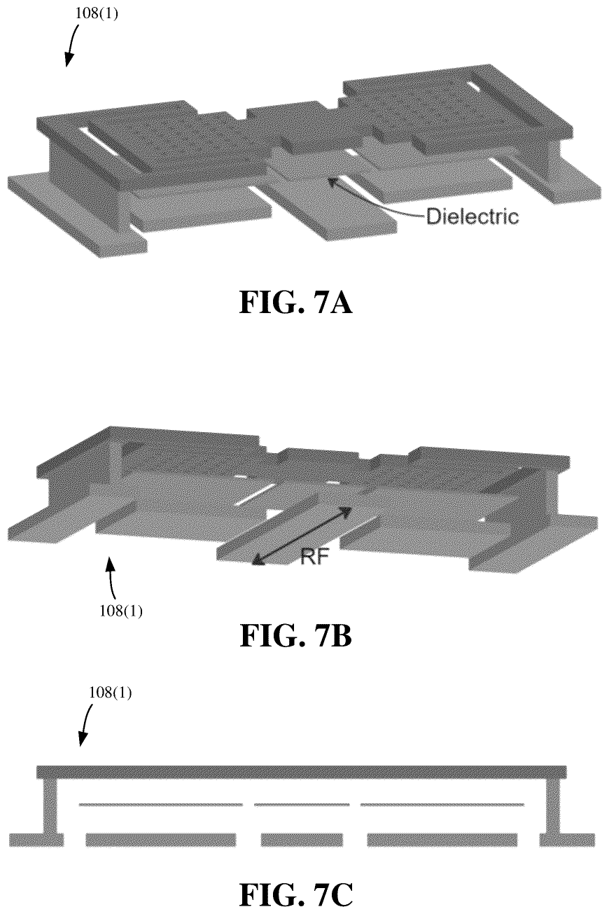

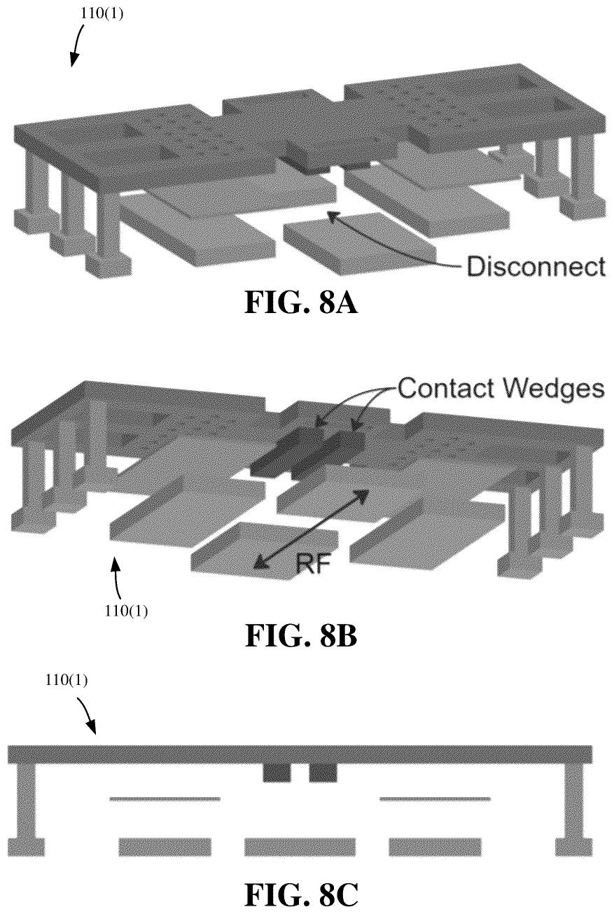

FIG. 6 shows details of an ohmic membrane switch-capacitive membrane switch pair, such as corresponding to the capacitive membrane switch 108(1) and the ohmic membrane switch 110(1) of FIG. 1. Such a switch pair can be implemented in a compact (e.g., 1 mm×0.5 mm) multiport switch as described herein, such as with two pairs (two ohmic membrane switches and two capacitive membrane switches). These devices can be designed to be actuated at the same voltage bias. By controlling the actuation and de-actuation, an RF signal applied at the RF In port can be routed to either the RF Out 1 port or the RF Out 2 port. As shown in FIG. 6, and in the 3D top, 3D bottom and cross-sectional views in FIG. 7A-7C, respectively, the capacitive membrane switch has a dielectric on the RF line, such that when actuated, the signal is shunted to RF ground. As shown in FIG. 6, and in the 3D top, 3D bottom and cross-sectional views in FIG. 8A-8C, respectively, the ohmic membrane switch has a disconnect between the RF line when de-actuated; when actuated, wedges (e.g., linear contact bars) make contact with the RF line.

The device facilitates failsafe operation if any of the switches fails, e.g., due to poor reliability. The failsafe RF switches are designed for redundancy and protection. In the event of certain types of failures, each such switch can provide isolation to protect the output circuitry coupled to the device to receive the RF signals. Design considerations include micro-welding protection, which can occur in contact-based switches, such as switch A 110(1) in FIG. 6, leading to failure. Redundant switches (Switch A and Switch B as in FIG. 6) ensure that if the ohmic switch fails due to micro-welding, the other can maintain operation as described herein.

High stress management is also provided; high fabrication stresses can increase the required pull-in voltage for actuation. Switch A 110(1) is designed with stiff flexures to prevent buckling, while Switch B 108(1) has a larger actuation area to compensate. Flexures can be optimized to reduce the von-Mises stress in the membranes, which reduces the stiffness.

Stiction prevention is also facilitated; capacitive switches can suffer from stiction, where the switch remains stuck in a down state. If switch B 108(1) experiences stiction and remains in the actuated state, the capacitive switch blocks the signal, (shunts the signal to RF ground), protecting the output.

With respect to failure scenarios, the dual switch design anticipates various failure modes, including that if switch A fails to actuate, the output circuitry is protected, as the RF line is physically disconnected and the wedges under the ohmic membrane fail to make contact and thus block the RF signal. If switch B 108(1) fails to actuate (remains lifted), the output remains controllable via switch A 110(1), as in the UP-state (de-actuated) mode, the capacitive switch allows signals to pass. If switch A 110(1) fails to recoil (is stuck in the DOWN-state, or actuated mode) due to micro-welding, stresses, dielectric charging, stiction or any reliability issues, the remaining switch B 108(1) can control the output, maintaining continuous functionality of the device. Only a simultaneous failure (switch A 110(1) fails to recoil and Switch B 108(1) fails to actuate) can lead to catastrophic failure, an extremely rare occurrence due to the redundancy.

It should be noted that it is feasible to use the redundancy of having two ohmic-capacitive switch pairs on a single device. If incoming RF signals stop being routed to connected circuitry via the RF output port 1, e.g., the ohmic membrane is stuck open or the capacitive membrane is stuck down shunting the signal to ground, the other output port 2 can be connected to the circuitry instead, with actuation/de-actuation control being changed to the other contact pads.

Turning to manufacturing one such example switch device 102, the membranes can be manufactured with any conductive material such as aluminum, copper, gold, or silver. Note that these and the other materials described in the manufacturing process are nonlimiting examples.

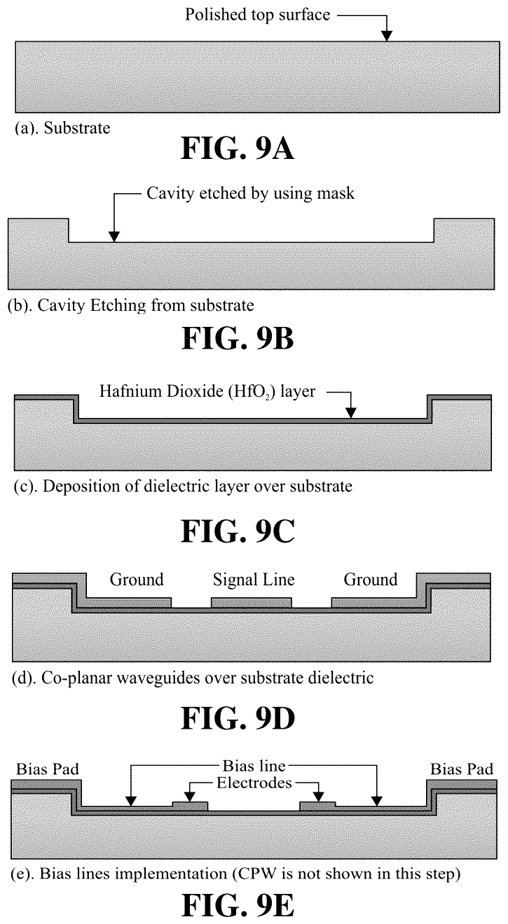

As shown in FIG. 9A corresponding to step (a), the process starts with a substrate having a polished top surface. Step (b) of FIG. 9B shows a cavity etched from the substrate by using a mask. Step (c) of FIG. 9C shows deposition of a dielectric layer (e.g., a Hafnium Dioxide (HfO₂)) layer over the substrate.

FIG. 9D, step (d) shows deposition of the metal coplanar waveguides over the substrate dielectric layer of FIG. 9C. The bias pads are added at step (e) of FIG. 9; note that given the side view, for visibility of the bias pads, the metal coplanar waveguides (CPW) are omitted from view in this step.

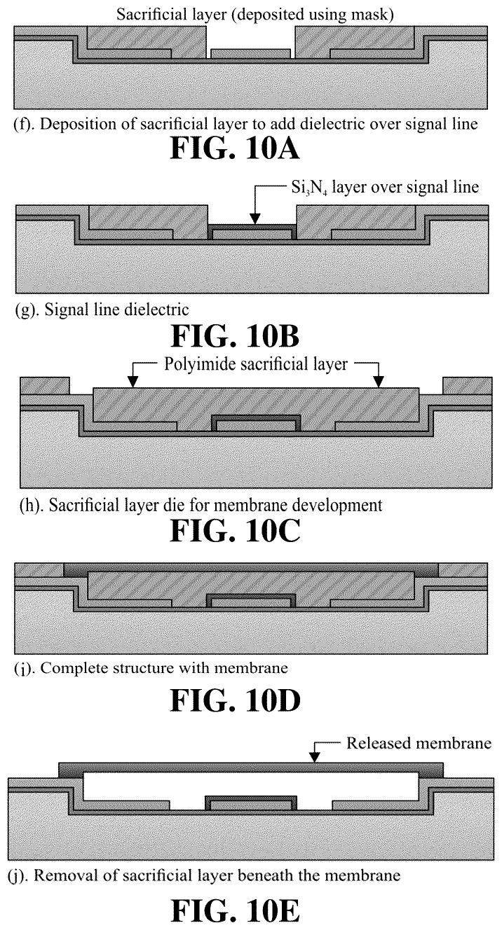

The manufacturing/fabrication process continues at FIG. 10A, step (f), where a sacrificial layer (deposited using mask) facilitates adding a dielectric over signal line, e.g., a Si₃N₄ (silicon nitride) layer is deposited over the over signal line dielectric at FIG. 10B, step (g). FIG. 10C, step (h), shows adding a polyimide sacrificial layer die for membrane development. FIG. 10D, step (i), shows the complete structure including the membrane. The membrane is then released, step (j) by removal of the sacrificial layer beneath the membrane, as shown in FIG. 10E.

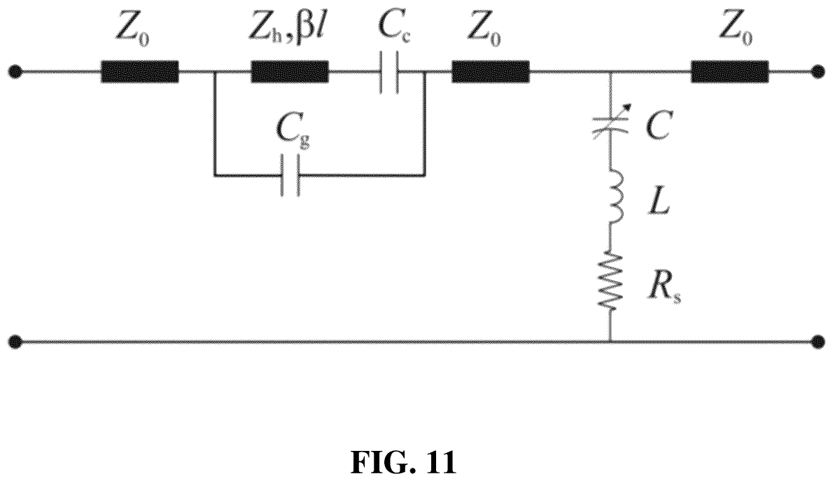

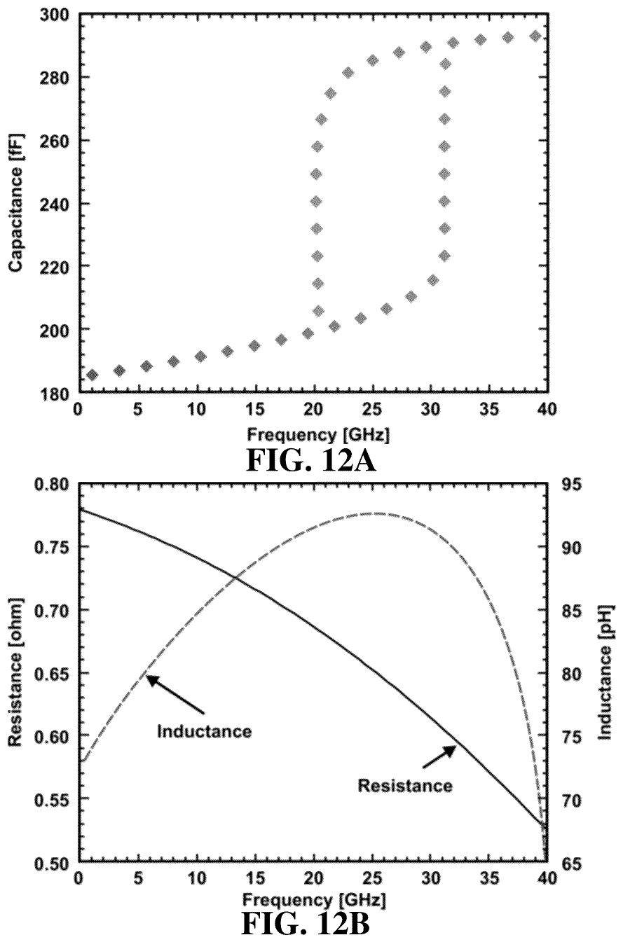

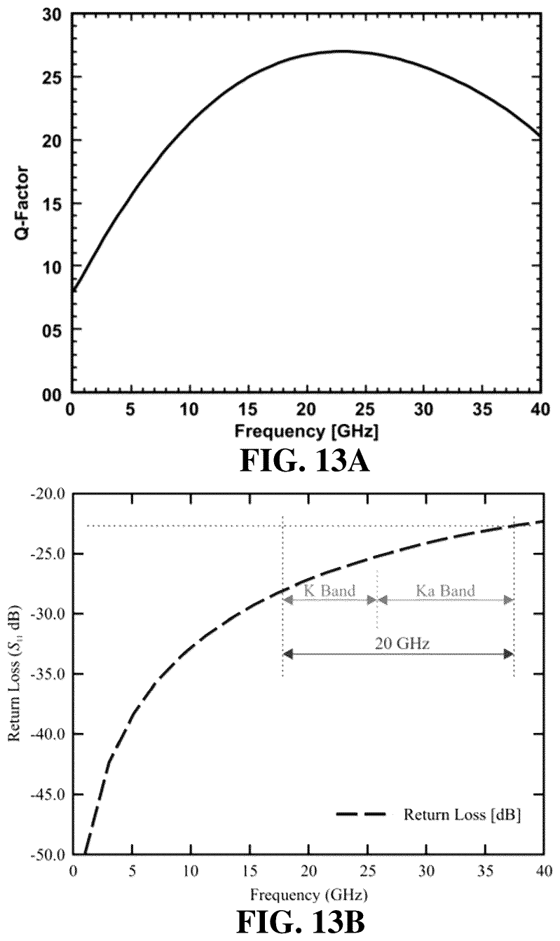

FIG. 11 shows an equivalent circuit model schematic of an example ohmic capacitive switch used in simulations, to evaluate the capacitance, the resistance/inductance and the Q-factor of the device over the frequency range of zero to 40 gigahertz. FIG. 12A graphically shows the capacitance change, FIG. 12B graphically shows the resistance and inductance change and FIG. 13A graphically shows the Q-factor change as the frequency is varied over the frequency range.

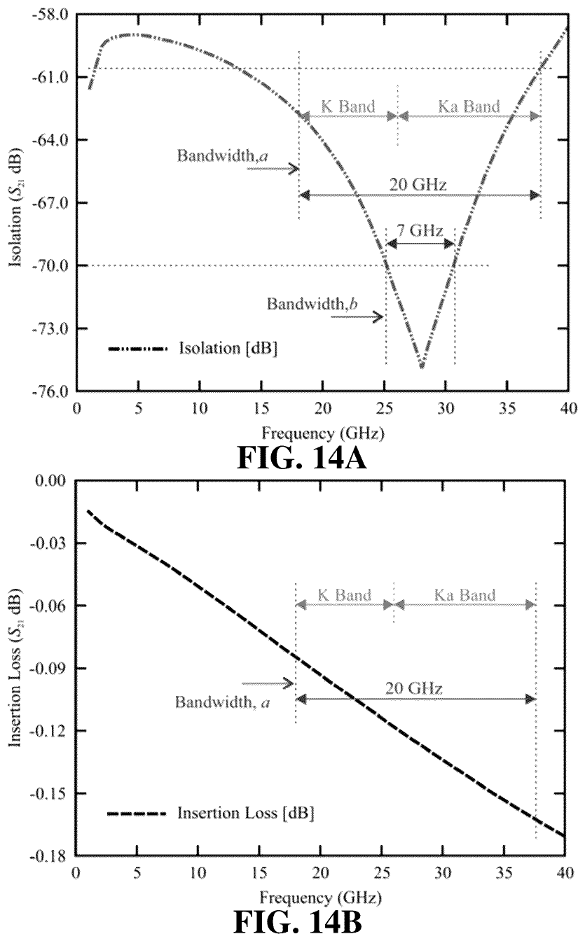

FIGS. 13B, 14A and 14B show the RF performance response on a dB scale. More particularly FIG. 13B shows the return loss, FIG. 14A shows the isolation, and FIG. 14B shows the insertion loss. As can be seen, a 20 gigahertz bandwidth in the K band and Ka band are covered by the device.

One or more implementations can be embodied in a device, including a radio frequency (RF) switch. The RF switch can include an ohmic membrane-based switch deployed in an RF signal path from an input port towards an output port. The ohmic membrane-based switch is controllable to be in an first actuated state or a first de-actuated state, in which the ohmic membrane-based switch is configured to, in the first actuated state, couple an RF transmission line that is part of the RF signal path to route RF signals obtained on the input port towards the output port, and in the first de-actuated state, decouple the RF transmission line from the signal path to prevent the RF signals obtained on the input port from being obtained by the output port. The RF switch can include a capacitive membrane-based switch deployed in the signal path. The capacitive membrane-based switch is controllable to be in a second actuated state or a second de-actuated state, in which the capacitive membrane-based switch is configured to, in the second de-actuated state, in conjunction with the ohmic membrane-based switch being in the first actuated state, pass the RF signals obtained on the input port to the output port, and in the second actuated state, shunt the RF signals obtained on the input port to an RF ground.

The ohmic membrane-based switch can be deployed in the RF signal path between the input port and the capacitive membrane-based switch, or the capacitive membrane-based switch is deployed in the RF signal path between the input port and the ohmic membrane-based switch.

The capacitive membrane-based switch can be deployed in the RF signal path between the ohmic membrane-based switch and the output port, or the ohmic membrane-based switch can be deployed in the RF signal path between the capacitive membrane-based switch and the output port.

The RF switch can be controlled to be in the first actuated state in conjunction with the RF-switch being controlled to be in the second de-actuated state.

The RF switch can be controllable to be in the first actuation state to route RF signals from the input port to the output port independent of the capacitive membrane-based switch remaining in the second de-actuated state as a result of failing to be controllable into the first de-actuated state. The RF switch can be controllable to be in the second de-actuated state independent of the ohmic membrane-based switch remaining in the first de-actuated state as a result of failing to recoil.

The RF switch can block the RF signals in response to the ohmic membrane-based switch remaining in the first de-actuated state as a result of failure of the ohmic membrane-based switch.

The RF switch can shunt the RF signals obtained on the input port to the RF ground in response to the capacitive membrane-based switch remaining in the second actuated state as a result of failure of the capacitive membrane-based switch.

The device further can include a first bias contact coupled to the ohmic membrane-based switch via a first resistive element, and a second bias contact coupled to the capacitive membrane-based switch via a second resistive element.

The ohmic membrane-based switch can be controlled to be in the first actuated state by application of a first voltage applied to the first bias contact; the ohmic membrane-based switch can be controlled to be in the first de-actuated state by removal of the first voltage from the first bias contact, the capacitive membrane-based switch can be controlled to be in the second actuated state by application of a second voltage applied to the second bias contact, and the capacitive membrane-based switch can be controlled to be in the second de-actuated state by removal of the second voltage from the second bias contact.

The first voltage and the second voltage can be equal to or substantially equal to one another.

The ohmic membrane-based switch can include a first ohmic membrane-based switch deployed in a first RF signal path from the input port towards a first output port, the capacitive membrane-based switch can include a first capacitive membrane-based switch deployed in the first RF signal path from the input port towards the first output port, the RF transmission line can be a first RF transmission line, the RF signals can include first RF signals, and the device further can include a second ohmic membrane-based switch deployed in a second RF signal path from the input port towards a second output port, the second ohmic membrane-based switch being controllable to be in an third actuated state or a third de-actuated state, the second ohmic membrane-based switch configured to, in the third actuated state, couple a second RF transmission line that can be part of the second RF signal path to route second RF signals obtained on the input port towards the second output port, and in the third de-actuated state, decouple the RF transmission line from the second signal path to prevent the second RF signals obtained on the input port from being obtained by the second output port, and a second capacitive membrane-based switch deployed in the second signal path, the second capacitive membrane-based switch being controllable to be in a fourth actuated state or a fourth de-actuated state, the second capacitive membrane-based switch configured to, in the fourth de-actuated state, in conjunction with the second ohmic membrane-based switch being in the third actuated state, pass the second RF signals obtained on the input port to the second output port, and in the fourth actuated state, shunt the second RF signals obtained on the input port to the RF ground.

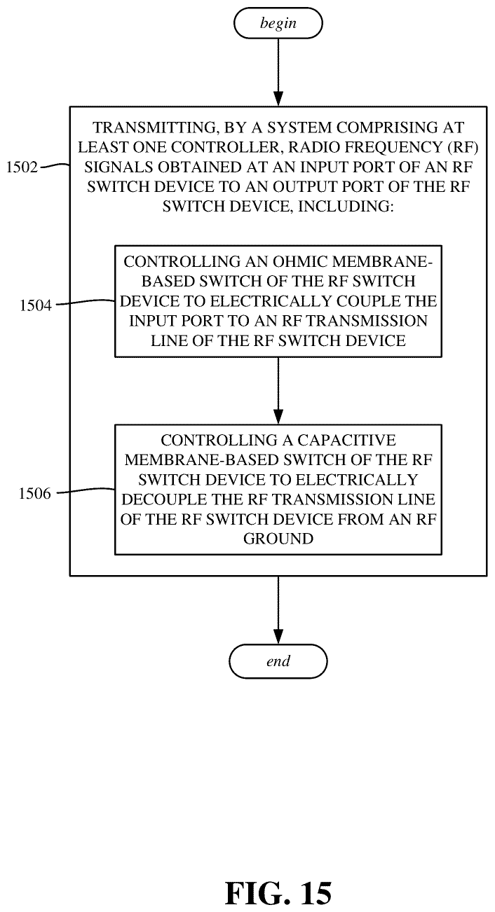

One or more example embodiments, implementations, and/or operations, such as corresponding to example operations of a method, can be represented in FIG. 15. Example operation 1502 represents transmitting, by a system comprising at least one controller, radio frequency (RF) signals obtained at an input port of an RF switch device to an output port of the RF switch device, which can include example operations 1504 and 1506. Example operation 1504 represents controlling an ohmic membrane-based switch of the RF switch device to electrically couple the input port to an RF transmission line of the RF switch device. Example operation 1504 represents controlling a capacitive membrane-based switch of the RF switch device to electrically decouple the RF transmission line of the RF switch device from an RF ground.

Further operations can include halting, by the at least one controller, transmission of further RF signals obtained at the input port from being transmitted to the output port, which can include controlling the ohmic membrane-based switch of the RF switch device to electrically decouple the input port from the RF transmission line of the RF switch device.

Further operations can include halting, by the at least one controller, transmission of further RF signals obtained at the input port from being transmitted to the output port, which can include controlling the capacitive membrane-based switch of the RF switch device to capacitively couple the RF transmission line of the RF switch device to the RF ground.

Controlling the ohmic membrane-based switch can include applying an actuation voltage to a voltage contact coupled to the ohmic membrane-based switch to actuate the ohmic membrane-based switch.

Controlling the capacitive membrane-based switch can include removing an actuation voltage from a voltage contact coupled to the capacitive membrane-based switch to de-actuate the ohmic membrane-based switch.

One or more implementations can be embodied in a system. The system can include at least one controller, an ohmic membrane-based switch coupled to the at least one controller, the ohmic membrane-based switch deployed in an radio frequency (RF) signal path from an input port towards an output port, the ohmic membrane-based switch controlled by the controller to operate in an actuated state that couples an RF transmission line from the input towards the output port, and a capacitive membrane-based switch coupled to the at least one controller, the capacitive membrane-based switch deployed in the RF signal path, the capacitive membrane-based switch controlled by the at least one controller to operate in an de-actuated state that decouples the RF transmission line from an RF ground.

The ohmic membrane-based switch can include a first ohmic membrane-based switch deployed in a first RF signal path from the input port towards a first output port, the capacitive membrane-based switch can include a first capacitive membrane-based switch deployed in the first RF signal path from the input port towards the first output port, the RF transmission line can be a first RF transmission line, the actuated state can be a first actuated state, the de-actuated state can be a first de-actuated state, and the system further can include a second ohmic membrane-based switch coupled to the at least one controller, the second ohmic membrane-based switch deployed in a second RF signal path from the input port towards a second output port, and the second ohmic membrane-based switch controlled by the at least one controller to operate in a second actuated state that couples a second RF transmission line from the input towards the second output port, and a second capacitive membrane-based switch coupled to the controller, the second capacitive membrane-based switch deployed in the second RF signal path, and the second capacitive membrane-based switch controlled by the controller to operate in a second de-actuated state that decouples the RF transmission line from the RF ground.

The actuated state can be a first actuated state, the de-actuated state can be a first de-actuated state, and at least one of: the ohmic membrane-based switch can be controlled by the controller to operate in a second de-actuated state that decouples the RF transmission line from the input port, or the capacitive membrane-based switch can be controlled by the controller to operate in a second actuated state that couples the RF transmission line to the RF ground.

As can be seen, the technology described herein facilitates a multiport RF switch based on dual-membrane operation, which can be on common voltage bias. The use of both ohmic and capacitive membranes, actuated at the same voltage, provides flexibility in signal routing and enhances robustness against membrane failures. Via the combined ohmic and capacitive membranes, a failsafe mechanism is inherent in such a switch. If one switch membrane fails, depending on the type of failure, the counterpart membrane type can controllably maintain the RF path, or block the RF path, protecting the output circuitry in certain failure situations.

The optimized flexure design reduces von Mises stress in the membranes, which helps to reduce or minimize the likelihood of stress-induced failures and improve the long-term durability of the switch. Enhanced reliability for better manufacturing yield can be accomplished by including contact wedged in the ohmic membrane and using independent pads for electrostatic actuation.

What has been described above include mere examples. It is, of course, not possible to describe every conceivable combination of components, materials or the like for purposes of describing this disclosure, but one of ordinary skill in the art can recognize that many further combinations and permutations of this disclosure are possible. Furthermore, to the extent that the terms “includes,” “has,” “possesses,” and the like are used in the detailed description, claims, appendices and drawings such terms are intended to be inclusive in a manner similar to the term “comprising” as “comprising” is interpreted when employed as a transitional word in a claim.

The descriptions of the various embodiments have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A device, comprising:
a radio frequency (RF) switch, comprising:
an ohmic membrane-based switch deployed in an RF signal path from an input port towards an output port, the ohmic membrane-based switch being controllable to be in an first actuated state or a first de-actuated state, the ohmic membrane-based switch configured to:
in the first actuated state, couple an RF transmission line that is part of the RF signal path to route RF signals obtained on the input port towards the output port, and
in the first de-actuated state, decouple the RF transmission line from the signal path to prevent the RF signals obtained on the input port from being obtained by the output port; and
a capacitive membrane-based switch deployed in the signal path, the capacitive membrane-based switch being controllable to be in a second actuated state or a second de-actuated state, the capacitive membrane-based switch configured to:
in the second de-actuated state, in conjunction with the ohmic membrane-based switch being in the first actuated state, pass the RF signals obtained on the input port to the output port, and
in the second actuated state, shunt the RF signals obtained on the input port to an RF ground.

2. The device of claim 1, wherein the ohmic membrane-based switch is deployed in the RF signal path between the input port and the capacitive membrane-based switch, or wherein the capacitive membrane-based switch is deployed in the RF signal path between the input port and the ohmic membrane-based switch.

3. The device of claim 1, wherein the capacitive membrane-based switch is deployed in the RF signal path between the ohmic membrane-based switch and the output port, or wherein the ohmic membrane-based switch is deployed in the RF signal path between the capacitive membrane-based switch and the output port.

4. The device of claim 1, wherein the RF switch is controlled to be in the first actuated state in conjunction with the RF-switch being controlled to be in the second de-actuated state.

5. The device of claim 4, wherein the RF switch is controllable to be in the first actuation state to route RF signals from the input port to the output port independent of the capacitive membrane-based switch remaining in the second de-actuated state as a result of failing to be controllable into the first de-actuated state.

6. The device of claim 4, wherein the RF switch is controllable to be in the second de-actuated state independent of the ohmic membrane-based switch remaining in the first de-actuated state as a result of failing to recoil.

7. The device of claim 1, wherein the RF switch blocks the RF signals in response to the ohmic membrane-based switch remaining in the first de-actuated state as a result of failure of the ohmic membrane-based switch.

8. The device of claim 1, wherein the RF switch shunts the RF signals obtained on the input port to the RF ground in response to the capacitive membrane-based switch remaining in the second actuated state as a result of failure of the capacitive membrane-based switch.

9. The device of claim 1, further comprising a first bias contact coupled to the ohmic membrane-based switch via a first resistive element, and a second bias contact coupled to the capacitive membrane-based switch via a second resistive element.

10. The device of claim 9, wherein the ohmic membrane-based switch is controlled to be in the first actuated state by application of a first voltage applied to the first bias contact, wherein the ohmic membrane-based switch is controlled to be in the first de-actuated state by removal of the first voltage from the first bias contact, wherein the capacitive membrane-based switch is controlled to be in the second actuated state by application of a second voltage applied to the second bias contact, and wherein the capacitive membrane-based switch is controlled to be in the second de-actuated state by removal of the second voltage from the second bias contact.

11. The device of claim 10, wherein the first voltage and the second voltage are equal to or substantially equal to one another.

12. The device of claim 1, wherein the ohmic membrane-based switch comprises a first ohmic membrane-based switch deployed in a first RF signal path from the input port towards a first output port, wherein the capacitive membrane-based switch comprises a first capacitive membrane-based switch deployed in the first RF signal path from the input port towards the first output port, wherein the RF transmission line is a first RF transmission line, wherein the RF signals comprise first RF signals, and further comprising:
a second ohmic membrane-based switch deployed in a second RF signal path from the input port towards a second output port, the second ohmic membrane-based switch being controllable to be in an third actuated state or a third de-actuated state, the second ohmic membrane-based switch configured to:
in the third actuated state, couple a second RF transmission line that is part of the second RF signal path to route second RF signals obtained on the input port towards the second output port, and
in the third de-actuated state, decouple the RF transmission line from the second signal path to prevent the second RF signals obtained on the input port from being obtained by the second output port; and
a second capacitive membrane-based switch deployed in the second signal path, the second capacitive membrane-based switch being controllable to be in a fourth actuated state or a fourth de-actuated state, the second capacitive membrane-based switch configured to:
in the fourth de-actuated state, in conjunction with the second ohmic membrane-based switch being in the third actuated state, pass the second RF signals obtained on the input port to the second output port, and
in the fourth actuated state, shunt the second RF signals obtained on the input port to the RF ground.

13. A method, comprising:
transmitting, by a system comprising at least one controller, radio frequency (RF) signals obtained at an input port of an RF switch device to an output port of the RF switch device, comprising:
controlling an ohmic membrane-based switch of the RF switch device to electrically couple the input port to an RF transmission line of the RF switch device; and
controlling a capacitive membrane-based switch of the RF switch device to electrically decouple the RF transmission line of the RF switch device from an RF ground.

14. The method of claim 13, further comprising halting, by the at least one controller, transmission of further RF signals obtained at the input port from being transmitted to the output port, comprising controlling the ohmic membrane-based switch of the RF switch device to electrically decouple the input port from the RF transmission line of the RF switch device.

15. The method of claim 13, further comprising halting, by the at least one controller, transmission of further RF signals obtained at the input port from being transmitted to the output port, comprising controlling the capacitive membrane-based switch of the RF switch device to capacitively couple the RF transmission line of the RF switch device to the RF ground.

16. The method of claim 13, wherein the controlling of the ohmic membrane-based switch comprises applying an actuation voltage to a voltage contact coupled to the ohmic membrane-based switch to actuate the ohmic membrane-based switch.

17. The method of claim 13, wherein the controlling of the capacitive membrane-based switch comprises removing an actuation voltage from a voltage contact coupled to the capacitive membrane-based switch to de-actuate the ohmic membrane-based switch.

18. A system, comprising:
at least one controller;
an ohmic membrane-based switch coupled to the at least one controller, the ohmic membrane-based switch deployed in an radio frequency (RF) signal path from an input port towards an output port, the ohmic membrane-based switch controlled by the controller to operate in an actuated state that couples an RF transmission line from the input towards the output port, and
a capacitive membrane-based switch coupled to the at least one controller, the capacitive membrane-based switch deployed in the RF signal path, the capacitive membrane-based switch controlled by the at least one controller to operate in an de-actuated state that decouples the RF transmission line from an RF ground.

19. The system of claim 18, wherein the ohmic membrane-based switch comprises a first ohmic membrane-based switch deployed in a first RF signal path from the input port towards a first output port, wherein the capacitive membrane-based switch comprises a first capacitive membrane-based switch deployed in the first RF signal path from the input port towards the first output port, wherein the RF transmission line is a first RF transmission line, wherein the actuated state is a first actuated state, wherein the de-actuated state is a first de-actuated state, and further comprising:
a second ohmic membrane-based switch coupled to the at least one controller, the second ohmic membrane-based switch deployed in a second RF signal path from the input port towards a second output port, and the second ohmic membrane-based switch controlled by the at least one controller to operate in a second actuated state that couples a second RF transmission line from the input towards the second output port, and
a second capacitive membrane-based switch coupled to the controller, the second capacitive membrane-based switch deployed in the second RF signal path, and the second capacitive membrane-based switch controlled by the controller to operate in a second de-actuated state that decouples the RF transmission line from the RF ground.

20. The system of claim 18, wherein the actuated state is a first actuated state, wherein the de-actuated state is a first de-actuated state, and wherein at least one of:
the ohmic membrane-based switch is controlled by the controller to operate in a second de-actuated state that decouples the RF transmission line from the input port, or
the capacitive membrane-based switch is controlled by the controller to operate in a second actuated state that couples the RF transmission line to the RF ground.
